(19) United States
(12) Patent Application Publication
(10) Pub. No.: US 2002/0075662 A1
(43) Pub. Date: Jun. 20, 2002

(54) Stack-type expansible electronic device

(75) Inventor: Eric Oh-Yang, Hsinchu City (TW)

Correspondence Address: DARBY & DARBY, 805 Third Avenue, New York, NY, 10022-7513, US

(73) Assignee: ABOCOM SYSTEMS, INC.

(21) Appl. No.: 09/779,172

(22) Filed: Feb. 8, 2001

(30) Foreign Application Priority Data
Dec. 19, 2000 (TW) 089222033

(51) Int. Cl. H05K 1/14

(52) U.S. Cl. 361/790

(57) ABSTRACT

A stack-type expansible electronic device includes a primary circuit board unit and at least one auxiliary circuit board unit. The primary circuit board unit includes a primary substrate having first and second major surfaces, which are respectively formed with substrate terminals and board terminals that extend transversely therefrom. One of the first and second major surfaces is further formed with a signal distribution circuit that is connected electrically to the substrate and board terminals. The auxiliary circuit board unit includes an auxiliary substrate having third and fourth major surfaces, and a set of conductive vias that extend from the third major surface through the fourth major surface and that permit the substrate terminals to extend respectively therethrough such that the auxiliary substrate is spaced apart from the primary substrate and such that the conductive vias are connected electrically to the signal distribution circuit via the substrate terminals. At least one of the third and fourth major surfaces has at least one expansion circuit component mounted thereon, and is formed with circuit traces for interconnecting electrically the conductive vias and the expansion circuit component.

### BACKGROUND OF THE INVENTION

1. Field of the Invention

The invention relates to a stack-type expansible electronic device, more particularly to a stack-type expansible electronic device that permits addition of expansion components without taking up much space.

2. Description of the Related Art

In the pursuit to enhance the functions of electronic products, addition of more electronic components is unavoidable, which means increased size of the electronic products. In view of the trend toward miniaturization of electronic products, increasing the relative density of the electronic components of the electronic products is a solution to increasing the functions of the electronic products without incurring a considerable increase in size.

FIG. 1 shows a conventional memory module 1 adapted for use in a computer. The memory module 1 stores programs and instructions necessary for operation of the computer, as well as data files. The memory module 1 is shown to include a printed circuit board 11 and a plurality of memory units 12. The entire memory module 1 is insertably mounted on a motherboard via gold fingers to permit data transmission. With the increase in data processing speed and the amount of data to be processed, there is a greater demand for larger memory capacity. To increase the memory capacity, the conventional method is to add more memory modules 1 or to augment the surface area of the printed circuit board 11 for mounting a larger number of memory units 12 thereon. However, increase of the surface area of the printed circuit board 11 will result in increased height of the computer, which goes against the trend toward miniaturization of electronic products, particularly for notebook computers and personal digital assistants.

### SUMMARY OF THE INVENTION

Therefore, the main object of the present invention is to provide a stack-type expansible electronic device that permits addition of expansion components without taking up much space.

Accordingly, a stack-type expansible electronic device of this invention includes a primary circuit board unit and at least one auxiliary circuit board unit. The primary circuit board unit includes a primary substrate having a first major surface and a second major surface opposite to the first major surface. The first major surface is formed with a set of substrate terminals that extend transversely therefrom. The second major surface is formed with a set of board terminals that extend transversely therefrom. One of the first and second major surfaces is further formed with a signal distribution circuit that is connected electrically to the substrate and board terminals. The auxiliary circuit board unit includes an auxiliary substrate having a third major surface and a fourth major surface opposite to the third major surface. The auxiliary substrate further has a set of conductive vias that extend from the third major surface through the fourth major surface and that permit the substrate terminals to extend respectively therethrough such that the auxiliary substrate is spaced apart from the primary substrate and such that the conductive vias are connected electrically to the signal distribution circuit via the substrate terminals. At least one of the third and fourth major surfaces has at least one expansion circuit component mounted thereon, and is formed with a plurality of circuit traces for interconnecting electrically the conductive vias and the expansion circuit component.

### BRIEF DESCRIPTION OF THE DRAWINGS

Other features and advantages of the present invention will become apparent in the following detailed description of the preferred embodiment with reference to the accompanying drawings, of which:

FIG. 1 is an exploded perspective view of a conventional memory module;

FIG. 2 is an exploded perspective view of the preferred embodiment of a stack-type expansible electronic device according to the present invention;

FIG. 3 is an assembled perspective view of the preferred embodiment, which is embodied in a memory module; and

FIG. 4 is a schematic side view of the memory module embodying the present invention.

### DETAILED DESCRIPTION OF THE PREFERRED EMBODIMENT

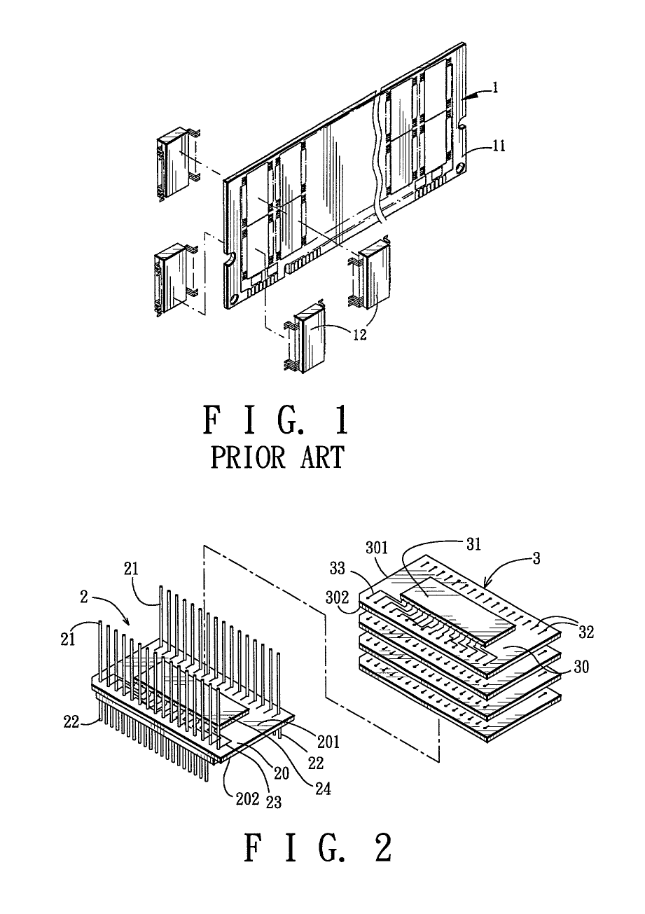

Referring to FIGS. 2 to 4, the preferred embodiment of a stack-type expansible electronic device according to the present invention is shown to be embodied in a memory module 4 that includes a primary circuit board unit 2 and at least one auxiliary circuit board unit 3 shaped to match the primary board unit 2. In this embodiment, the electronic device is a memory device.

The primary circuit board 2 includes a primary substrate 20 having a first major surface 201 and a second major surface 202 opposite to the first major surface 201. The first major surface 201 is formed with a set of substrate terminals 21 that extend transversely therefrom. The primary substrate 20 further has opposite longitudinal edges. In this embodiment, two sets of substrate terminals 21 are disposed on the first major surface 201 and adjacent to the longitudinal edges, respectively. The second major surface 202 is formed with a set of board terminals 22 that extend transversely therefrom. In this embodiment, two sets of board terminals 22 are disposed on the second major surface 202 and adjacent to the longitudinal edges, respectively. One of the first and second major surfaces 201, 202 is further formed with a signal distribution circuit 23 that is connected electrically to the substrate and board terminals 21, 22. By virtue of the signal distribution circuit 23, electrical connection between the substrate and the board terminals 21, 22 does not require the arrangement of the substrate and board terminals 21, 22 to be in a one-to-one correspondence.

Each of the auxiliary circuit board units 3 includes an auxiliary substrate 30 having a third major surface 301 and a fourth major surface 302 opposite to the third major surface 301. The auxiliary substrate 30 further has a set of conductive vias 32 that extend from the third major surface 301 through the fourth major surface 302 and that permit the substrate terminals 21 to extend respectively therethrough such that the auxiliary substrate 30 is spaced apart from the primary substrate 20 and such that the conductive vias 32 are connected electrically to the signal distribution circuit 23 via the substrate terminals 21. At least one of the third and fourth major surfaces 301, 302 has at least one expansion circuit component 31 mounted thereon, and is formed with a plurality of circuit traces 33 for interconnecting electrically the conductive vias 32 and the expansion circuit component 31. In this embodiment, there are provided four auxiliary circuit board units 3, each having an expansion circuit component 31 disposed thereon. In addition, the expansion circuit component 31 is preferably a memory device.

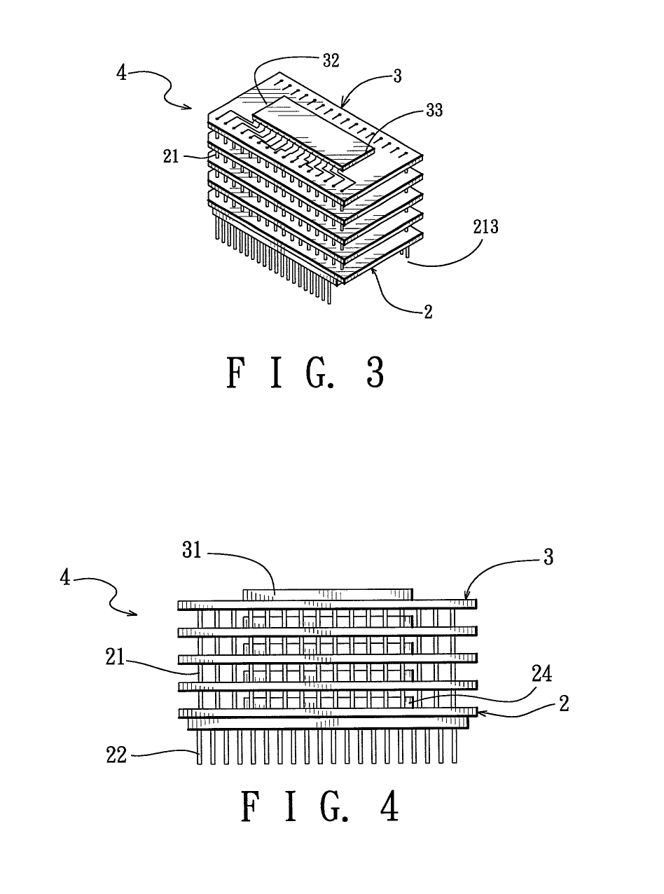

After assembly, referring to FIGS. 3 and 4, the length of the substrate terminals 21 extending from the first major surface 201 depends upon the number of auxiliary circuit board units 3 the substrate terminals 21 are configured to extend through. The conductive vias 32 are in frictional engagement with the substrate terminals 21. A bonding agent, such as solder, may be used to strengthen the engagement between each of the auxiliary circuit board units 3 and the substrate terminals 21 and to enhance electrical connection between the conductive vias 32, which are connected to the expansion circuit component 31 via the circuit traces 33, and the substrate terminals 21. As such, a stack of the auxiliary circuit board units 3 may be mounted on the primary circuit board unit 2 for expansion purposes, and the expansion circuit component 31 mounted on each of the auxiliary circuit board units 3 may be electrically connected to the board terminals 22 via the substrate terminals 21 and the signal distribution circuit 23 to perform signal transmission. In use, in order to control access of data to and from each of the expansion circuit components 31 on the auxiliary circuit board units 3, the primary circuit board unit 2 further includes a memory controller 24 mounted on one of the first and second major surfaces 201, 201 and connected electrically to the signal distribution circuit 23.

By virtue of the stack-type expansible electronic device of the present invention, a plurality of auxiliary circuit board units 3 may be stacked for mounting of a plurality of expansion circuit components 31. In this embodiment, since the entire memory module 4 is adapted to be placed flatly on a motherboard (not shown), it is not necessary to form an elongated insert slot in the motherboard. In addition, the surface area occupied by the memory module 4 is relatively small, and the height of the memory module 4 after mounting on the motherboard is likewise relatively small, as compared with the prior art. Thus, the overall size of the electronic product incorporating the memory module 4 according to this invention can be reduced.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

I claim:

1. A stack-type expansible electronic device, comprising:
a primary circuit board unit including a primary substrate having a first major surface and a second major surface opposite to said first major surface, said first major surface being formed with a set of substrate terminals that extend transversely therefrom, said second major surface being formed with a set of board terminals that extend transversely therefrom, one of said first and second major surfaces being further formed with a signal distribution circuit that is connected electrically to said substrate and board terminals; and
at least one auxiliary circuit board unit including an auxiliary substrate having a third major surface and a fourth major surface opposite to said third major surface, said auxiliary substrate further having a set of conductive vias that extend from said third major surface through said fourth major surface and that permit said substrate terminals to extend respectively therethrough such that said auxiliary substrate is spaced apart from said primary substrate and such that said conductive vias are connected electrically to said signal distribution circuit via said substrate terminals, at least one of said third and fourth major surfaces having at least one expansion circuit component mounted thereon and being formed with a plurality of circuit traces for interconnecting electrically said conductive vias and said expansion circuit component.

2. The stack-type expansible electronic device of claim 1, wherein said primary substrate has opposite longitudinal edges, at least one of said substrate and board terminals being disposed adjacent to said longitudinal edges of said primary substrate.

3. The stack-type expansible electronic device of claim 1, wherein said conductive vias are in frictional engagement with said substrate terminals.

4. The stack-type expansible electronic device of claim 1, wherein said expansion circuit component is a memory device.

5. The stack-type expansible electronic device of claim 4, wherein said primary circuit board unit further includes a memory controller mounted on one of said first and second major surfaces and connected electrically to said signal distribution circuit.
